(19) United States
(12) Patent Application Publication
(10) Pub. No.: US 2013/0200748 A1
(43) Pub. Date: Aug. 8, 2013

(54) PIEZOELECTRIC ACTUATOR INCLUDING Ti/TiOx ADHESIVE LAYER AND ITS MANUFACTURING METHOD

(71) Applicant: STANLEY ELECTRIC CO., LTD., Tokyo (JP)

(72) Inventor: Susumu NAKAMURA, Tokyo (JP)

(73) Assignee: STANLEY ELECTRIC CO., LTD., Tokyo (JP)

(21) Appl. No.: 13/751,845

(22) Filed: Jan. 28, 2013

(30) Foreign Application Priority Data
Feb. 3, 2012 (JP) 2012-021510

(51) Int. Cl. H01L 41/08; H01L 41/27

(52) U.S. Cl. CPC H01L 41/0805; H01L 41/27
USPC 310/311; 204/192.1

(57) ABSTRACT

A piezoelectric actuator includes a substrate, an oxide layer formed on the substrate, a Ti0ₓ (0<x≦2) adhesive layer formed on the oxide layer, a Ti adhesive layer formed on the Ti0ₓ adhesive layer, a Pt lower electrode layer formed on the Ti adhesive layer, and a PZT piezoelectric layer formed on the Pt lower electrode layer.

This application claims the priority benefit under 35 U.S.C. §119 to Japanese Patent Application No. JP2012-021510 filed on Feb. 3, 2012, which disclosure is hereby incorporated in its entirety by reference.

### BACKGROUND

1. Field

The presently disclosed subject matter relates to a piezoelectric actuator including lead titanate zirconate (PZT) and its manufacturing method.

2. Description of the Related Art

Lead titanate zirconate PbZrₓTi₁₋ₓ0₃ (PZT), which is an oxide compound including lead (Pb), zirconium (Zr) and titanium (Ti), has a simple cubic-system perovskite crystal structure as illustrated in FIG. 9. In FIG. 9, note that a shaded sphere indicates Pb, a black sphere indicates Zr or Ti, and a white sphere indicates oxygen (O). As illustrated in FIG.

10, which is a graph for showing an X-ray diffractive pattern of PZT of FIG. 9, PZT generates a polarization when PZT is distorted along its <100> direction or <111> direction, thus exhibiting an excellent piezoelectric characteristic when PZT has an orientation of (100) or (111) (see: FIGS. 5 and 10 of JP2003-81694A). That is, the crystal structure of PZT constitutes a tetragonal-system or a rhombohedral-system. In the tetragonal-system crystal structure of PZT, the largest piezoelectric displacement is obtained along the <100> direction (the a-axis direction) (or the <001> direction (the c-axis direction)), while, in the rhombohedral-system crystal structure of PZT, the largest piezoelectric displacement is obtained along the <111> direction. Also, as to the breakdown voltage characteristic which is an important characteristic for piezoelectric actuators, titanium (Ti)-rich (x<0.5) tetragonal-system PZTs are advantageous over rhombohedral-system PZTs. Therefore, PZT piezoelectric layers using such tetragonal⁻system PZTs are used for micro electro mechanical systems (MEMS) elements as actuators, MEMS elements as sensors, electricity generating elements, gyro elements and so on.

In FIG. 11, which is a cross-sectional view illustrating a first prior art piezoelectric actuator, this piezoelectric actuator is of a laminated capacitor type which includes a monocrystalline silicon substrate 1, an about 500 nm thick silicon dioxide (Si0₂) layer 2, an about 50 nm thick titanium (Ti) adhesive layer 3A, an about 150 nm thick platinum (Pt) lower electrode layer 4, an about 3 μm thick PZT piezoelectric layer 5 and an about 300 nm thick Pt upper electrode layer 6. In this case, the monocrystalline silicon substrate 1 can be replaced by a silicon-on-insulator (SOI) substrate. Also, since the silicon dioxide layer 2 has bad adhesion characteristics with the Pt lower electrode layer 4, the Ti adhesive layer 3A is interposed therebetween in order to improve the adhesion characteristics between the silicon dioxide layer 2 and the Pt lower electrode layer 4 and relax a stress therebetween.

In FIG. 11, when the direction of the PZT piezoelectric layer 5 as indicated by an arrow is along the <100> direction or the <001> direction, distortion is effectively generated by applying a voltage between the Pt lower electrode layer 4 and the Pt upper electrode layer 6.

In the piezoelectric actuator of FIG. 11, however, when the PZT piezoelectric layer 5 is an arc discharge reactive ion plating (ADRIP) process, a sputtering process or a sol-gel process, one wafer including the PZT piezoelectric layer 5 is heated to about 500° C. As a result, as illustrated in FIG. 12, the Ti component of the Ti adhesive layer 3A is diffused into the Pt lower electrode layer 4. Also, the Pb component of the PZT piezoelectric layer 5 reacts with the Pt lower electrode layer 4 and is further diffused into the Ti adhesive layer 3A and the silicon dioxide layer 2. Further, the Si component of the silicon dioxide layer 2 is diffused into the Ti adhesive layer 3A.

Thus, in the piezoelectric actuator of FIG. 11, as illustrated in FIG. 13A, the crystallizability of the Pt lower electrode layer 4 greatly fluctuates so that the surface roughness would be increased. Also, as illustrated in FIG. 13B, the crystallizability of the Pt lower electrode layer 4 within one wafer greatly fluctuates. In FIG. 13B, note that 4a indicates a portion where the crystallizability of the Pt lower electrode layer 4 is good, while 4b indicates a portion where the crystallizability of the Pt lower electrode layer 4 is bad. Therefore, as illustrated in FIG. 14A, the columnar crystallizability of the PZT piezoelectric layer 5 greatly fluctuates. Also, as illustrated in FIG. 14B, the piezoelectric constant (−d₃₁) of the PZT piezoelectric layer 5 within one wafer greatly fluctuates. In FIG. 14B, note that 5a indicates a portion where the piezoelectric constant (−d₃₁) is high, while 5b indicates a portion where the piezoelectric constant (−d₃₁) is low. Further, as illustrated in FIG. 15, the surface roughness of the Pt upper electrode layer 6 greatly fluctuates. Therefore, when a voltage is applied between the Pt lower electrode layer 4 and the Pt upper electrode layer 6, a strong electric field would be locally focused so that the breakdown voltage characteristics would deteriorate. Thus, the manufacturing yield would be decreased.

Also, in the piezoelectric actuator of FIG. 11, the adhesion between the Ti adhesive layer 3A and the Pt lower electrode layer 4 is carried out by metal-to-metal bonding, thus securing a strong adhesion. However, the adhesion between the Ti adhesive layer 3A and the silicon dioxide layer 2 is carried out by metal-to-oxide bonding using an intermolecular force or an electrostatic attraction, thus showing a weak adhesion W. Therefore, under a condition where the PZT piezoelectric layer 5 is of a traverse effect type, when the PZT piezoelectric layer 5 is contracted along the traverse direction as indicated by arrows X1 in FIG. 16, each of the Ti adhesive layer 3A, the Pt lower electrode layer 4 and the Pt upper electrode layer 6 would also be contracted by the contraction of the PZT piezoelectric layer 5, as indicated by arrows X2 in FIG. 16. Therefore, the weak bonding interface between the Ti adhesive layer 3A and the silicon dioxide layer 2 would be peeled off by the contraction of the PZT piezoelectric layer 5.

FIGS. 17A and 17B are graphs showing the dielectric loss coefficient tan δ and the capacitance deviation ΔC/C corresponding to the piezoelectric constant (−d₃₁) in response to an electric field E caused by applying an AC voltage V_{AC} between the Pt lower electrode layer 4 and the Pt upper electrode layer 6 of FIG. 11. As illustrated in FIGS. 17A and 17B, when the electric field E of the applied AC voltage V_{AC} is not larger than 26 V/μm (E≦26V/μm), the dielectric loss coefficient tan δ and the capacitance deviation ΔC/C are both unchanged, while the electric field E becomes larger than 26 V/μm (E>26V/μm), both of the dielectric loss coefficient tan δ and the capacitance deviation ΔC/C start to change. In this case, as illustrated in FIG. 18A, the peripheral surface of the piezoelectric actuator of FIG. 11, i. e., the peripheral surface of the Pt upper electrode layer 6 starts to be cracked. Further, when the electric field E of the applied AC voltage V_{AC} is increased, the Pt upper electrode layer 6 associated with the PZT piezoelectric layer 5, the Pt lower electrode layer 4 and the Ti adhesive layer 3A is entirely peeled off, as illustrated in FIG. 18B, thus inviting electrostatic destruction. Note that a dielectric loss coefficient represents a ratio of heat actually converted from an electric energy of the applied AC voltage with respect to this electric energy.

In the piezoelectric actuator of FIG. 11, an electric field E_{BD} corresponding to a breakdown voltage of the applied AC voltage is defined by 26 V/μm, i.e. , E_{BD}=26 V/μm.

In FIG. 19, which is a cross-sectional view illustrating a second prior art piezoelectric actuator, a Ti0₂ adhesive layer 3B is provided instead of the Ti adhesive layer 3A of FIG. 11. That is, no metal Ti is included in the Ti0₂ adhesive layer 3B.

In the piezoelectric actuator of FIG. 19, even when the PZT piezoelectric layer 5 is formed by an arc discharge reactive ion plating (ADRIP) process, a sputtering process or a sol-gel process, so that one wafer including the PZT piezoelectric layer 5 is heated to about 500° C., as illustrated in FIG. 20, no metal Ti is diffused into the Pt lower electrode layer 4. Also, even when the Pb component of the PZT piezoelectric layer 5 reacts with the Pt lower electrode layer 4, the diffusion of the Pb component into the Pt lower electrode layer 4 and the silicon dioxide layer 2 can be prevented by the oxygen component of the Ti0₂ adhesive layer 3B. Further, the oxygen component of the Ti0₂ adhesive layer 3B prevents the Si component of the silicon dioxide layer 2 from being diffused into the Ti0₂ adhesive layer 3B.

In the piezoelectric actuator of FIG. 19, the adhesion between the Ti0₂ adhesive layer 3B and the silicon dioxide layer 2 is carried out by oxide-to-oxide bonding such as covalent bonding or ion bonding, thus securing a strong adhesion. However, the adhesion between the Ti0₂ adhesive layer 3B and the Pt lower electrode layer 4 is carried out by metal-to-oxide bonding using an intermolecular force or an electrostatic attraction, thus showing a weak adhesion W. Therefore, under a condition where the PZT piezoelectric layer 5 is of a traverse effect type, when the PZT piezoelectric layer 5 is contracted along the traverse direction as indicated by arrows X1 in FIG. 21, each of the Pt lower electrode layer 4 and the Pt upper electrode layer 6 would also be contracted by the contraction of the PZT piezoelectric layer 5, as indicated by arrows X2 in FIG. 21. Therefore, the weak bonding interface between the Ti0₂ adhesive layer 3B and the Pt lower electrode layer 4 would be peeled off by the contraction of the PZT piezoelectric layer 5.

Thus, when the electric field E of the applied AC voltage becomes larger than E_{BD} which is, in this case, 53 V/μm, the peripheral surface of the piezoelectric actuator of FIG. 19, i. e., the peripheral surface of the Pt upper electrode layer 6 starts to be cracked. Further, when the electric field E of the applied AC voltage V_{AC} is increased, the Pt upper electrode layer 6 associated with the PZT piezoelectric layer 5 and the Pt lower electrode layer 4 is entirely peeled off, thus inviting electrostatic destruction.

In FIG. 22, which illustrates a third prior art piezoelectric actuator (see: JP2002-185285A), an x-graded Ti0ₓ (0≦x≦2) adhesive layer 3C is provided instead of the Ti adhesive layer 3A of FIG. 9. That is, the x-graded Ti0ₓ adhesive layer 3C is obtained by incompletely oxidizing Ti. The composition x of the x-graded Ti0ₓ adhesive layer 3C, for example, is continuously graded. Also, Ti0ₓ at an interface of the Ti0ₓ adhesive layer 3C in contact with the silicon dioxide layer 2 is Ti (x=0), while, Ti0ₓ at another interface of the x-graded Ti0ₓ adhesive layer 3C in contact with the Pt lower electrode layer 4 is Ti0₂ (x=2).

In the piezoelectric actuator of FIG. 22, even when the PZT piezoelectric layer 5 is formed by an arc discharge reactive ion plating (ADRIP) process, a sputtering process or a sol-gel process, so that one wafer including the PZT piezoelectric layer 5 is heated to about 500° C., as illustrated in FIG. 23, no metal Ti is diffused into the Pt lower electrode layer 4. Also, even when the Pb component of the PZT piezoelectric layer 5 reacts with the Pt lower electrode layer 4, the diffusion of the Pb component into the Pt lower electrode layer 4 and the silicon dioxide layer 2 can be prevented by the oxygen component of the x-graded Ti0ₓ adhesive layer 3C. Further, the oxygen component of the x-graded Ti0ₓ adhesive layer 3C prevents the Si component of the silicon dioxide layer 2 from being diffused into the x-graded Ti0ₓ adhesive layer 3C.

In the piezoelectric actuator of FIG. 22, the adhesion between the x-graded Ti0ₓ adhesive layer 3C (x=0) and the silicon dioxide layer 2 and the adhesion between the x-graded Ti0ₓ adhesive layer 3C (x=2) and the Pt lower electrode layer 4 are carried out by metal-to-oxide bonding using an intermolecular force or an electrostatic attraction, thus showing weak adhesions W. Therefore, under a condition where the PZT piezoelectric layer 5 is of a traverse effect type, when the PZT piezoelectric layer 5 is contracted along the traverse direction as indicated by arrows X1 in FIG. 24, each of the x-graded Ti0ₓ adhesive layer 3C, the Pt lower electrode layer 4 and the Pt upper electrode layer 6 would also be contracted by the contraction of the PZT piezoelectric layer 5, as indicated by arrows X2 in FIG. 24. Therefore, the weak bonding interface between the x-graded Ti0ₓ adhesive layer 3C and the silicon dioxide layer 2 (or the Pt lower electrode layer 4) would be peeled off by the contraction of the PZT piezoelectric layer 5.

Thus, when the electric field E of the applied AC voltage V_{AC} becomes larger than E_{BD}, the peripheral surface of the piezoelectric actuator of FIG. 22, i.e., the peripheral surface of the Pt upper electrode layer 6 starts to be cracked. Further, when the electric field E of the applied AC voltage V_{AC} is increased, the Pt upper electrode layer 6 associated with the PZT piezoelectric layer 5 and the Pt lower electrode layer 4 is entirely peeled off, thus inviting electrostatic destruction.

### SUMMARY

The presently disclosed subject matter seeks to solve one or more of the above-described problems.

According to the presently disclosed subject matter, a piezoelectric actuator includes a substrate, an oxide layer formed on the substrate, a Ti0ₓ (0<x≦2) adhesive layer formed on the oxide layer, a Ti adhesive layer formed on the Ti0ₓ adhesive layer, a Pt lower electrode layer formed on the Ti adhesive layer, and a PZT piezoelectric layer formed on the Pt lower electrode layer. Thus, adhesion between the oxide layer and the Ti0ₓ adhesive layer is carried out by oxide-to-oxide bonding such as covalent bonding or ion bonding, thus securing a strong adhesion, and adhesion between the Ti adhesive layer and the Pt lower electrode layer is carried out by metal-to-metal bonding, thus securing a strong adhesion. Also, if the Ti adhesive layer is thin, diffusion of the component Ti of the Ti adhesive layer into the Pt lower electrode layer is suppressed. Further, diffusion of the component Pb of the PZT piezoelectric layer into the Pt lower electrode layer, the Ti adhesive layer, the Ti0ₓ adhesive layer and the oxide layer is suppressed by the oxygen component of the Ti0ₓ adhesive layer.

Also, preferably, the composition x of the Ti0ₓ adhesive layer satisfies:

0<x<2

That is, Ti0ₓ of the Ti0ₓ adhesive layer excludes Ti0₂, and in this case, the Ti0ₓ adhesive layer is obtained by incompletely oxidizing Ti. Thus, the Ti0ₓ adhesive layer reacts with the Ti adhesive layer at their interface, so that the component Ti of the Ti adhesive layer is diffused into the Ti0ₓ adhesive layer, thus securing a strong adhesion between the Ti0ₓ adhesive layer and the Ti adhesive layer.

Further, preferably, the Ti adhesive layer is very thin, i. e., 10 to 20 nm thick. As a result, as stated above, diffusion of the component Ti of the Ti adhesive layer into the Pt lower electrode layer and its upper layers is suppressed.

On the one hand, in a method for manufacturing a piezoelectric actuator, an oxide layer is formed on a substrate. Then, a Ti0ₓ (0<x≦2) adhesive layer is formed on the oxide layer by a sputtering process using a constant flow rate of inert gas and a constant flow rate of oxygen gas. Then, a Ti adhesive layer is formed on the Ti0ₓ adhesive layer by a sputtering process using a constant flow rate of insert gas. Then, a Pt lower electrode layer is formed on the Ti0ₓ adhesive layer. Finally, a PZT piezoelectric layer is formed on the Pt lower electrode layer.

According to the presently disclosed subject matter, since the adhesion between the oxide layer and the Pt lower electrode layer is secured by the Ti/Ti0x adhesive layer, and the diffusion of the Pb component is suppressed, the crystallizability and polarization characteristics of PZT, as well as the breakdown voltage characteristics thereof, can be improved, thus improving the manufacturing yield.

### BRIEF DESCRIPTION OF THE DRAWINGS

The above and other advantages and features of the presently disclosed subject matter will be more apparent from the following description of certain embodiments, taken in conjunction with the accompanying drawings, as compared with the prior art, wherein:

FIG. 1 is a cross-sectional view illustrating an embodiment of the piezoelectric actuator according to the presently disclosed subject matter;

FIG. 2 is a cross-sectional view for explaining the diffusion characteristics in the piezoelectric actuator of FIG. 1;

FIG. 3 is a cross-sectional view for explaining the contracting operation of the piezoelectric actuator of FIG. 1;

FIG. 4A is a graph illustrating an X-ray analysis pattern of the PZT piezoelectric layer of FIG. 1;

FIG. 4B is a graph illustrating an orientation characteristic of the PZT piezoelectric layer of FIG. 1;

FIG. 5A is a graph showing the dielectric loss coefficient of the piezoelectric actuator of FIG. 1;

FIG. 5B is a graph showing the capacitance deviation of the piezoelectric actuator of FIG. 1;

FIG. 6 is a flowchart for explaining a method for manufacturing the piezoelectric actuator of FIG. 1;

FIG. 7 is a diagram illustrating an ADRIP apparatus used in the ADRIP pre-process step and the ADRIP main-process step of FIG. 6;

FIG. 8 is a scanning electron microscope (SEM) photograph illustrating a cross section of the Ti adhesive layer, the Pt lower electrode layer and the PZT piezoelectric layer of FIG. 1 as a comparative example;

FIG. 9 is a diagram illustrating a crystal structure of PZT;

FIG. 10 is a graph illustrating an X-ray diffractive pattern of PZT of FIG. 9;

FIG. 11 is a cross-sectional view illustrating a first prior art piezoelectric actuator;

FIG. 12 is a cross-sectional view for explaining the diffusion characteristics in the piezoelectric actuator of FIG. 11;

FIG. 13A is a scanning electron microscope (SEM) photograph illustrating a cross section of the Ti adhesive layer, the Pt lower electrode layer and the PZT piezoelectric layer of FIG. 11;

FIG. 13B is a photograph of a plan view of the Pt lower electrode layer of FIG. 11;

FIG. 14A is a scanning electron microscope (SEM) photograph illustrating a cross section of the PZT piezoelectric layer of FIG. 11;

FIG. 14B is a photograph of a plan view of the PZT piezoelectric layer of FIG. 11;

FIG. 15 is a scanning electron microscope (SEM) photograph illustrating a cross section of the Ti adhesive layer, the Pt lower electrode layer, the PZT piezoelectric layer and the Pt upper electrode layer of FIG. 11;

FIG. 16 is a cross-sectional view for explaining the contracting operation of the PZT piezoelectric actuator of FIG. 11;

FIG. 17A is a graph showing the dielectric loss coefficient of the piezoelectric actuator of FIG. 11;

FIG. 17B is a graph showing the capacitance deviation of the piezoelectric actuator of FIG. 11;

FIG. 18A is a photograph showing cracks in the peripheral portion of the Pt upper electrode layer of FIG. 11;

FIG. 18B is a photograph showing an electrostatic destruction state of the entire Pt upper electrode layer of FIG. 11;

FIG. 19 is a cross-sectional view illustrating a second prior art piezoelectric actuator;

FIG. 20 is a cross-sectional view for explaining the diffusion characteristics in the piezoelectric actuator of FIG. 19;

FIG. 21 is a cross-sectional view for explaining the contracting operation of the PZT piezoelectric actuator of FIG. 19;

FIG. 22 is a cross-sectional view illustrating a third prior art piezoelectric actuator;

FIG. 23 is a cross-sectional view for explaining the diffusion characteristics in the piezoelectric actuator of FIG. 22; and

FIG. 24 is a cross-sectional view for explaining the contracting operation of the PZT piezoelectric actuator of FIG. 22.

### DETAILED DESCRIPTION OF EXEMPLARY EMBODIMENTS

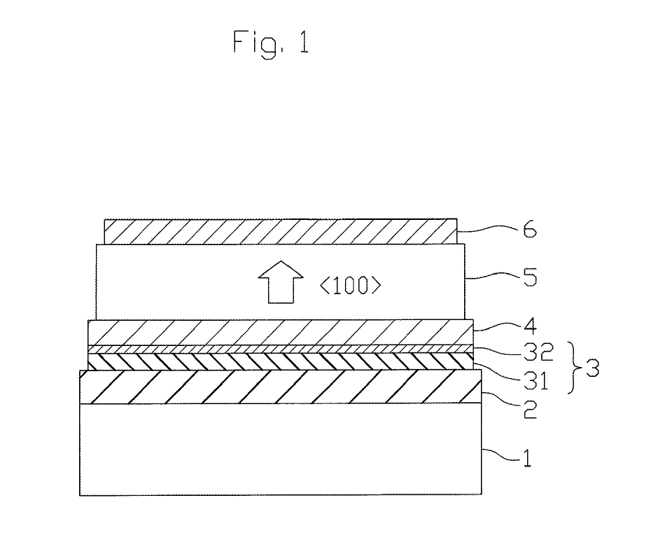

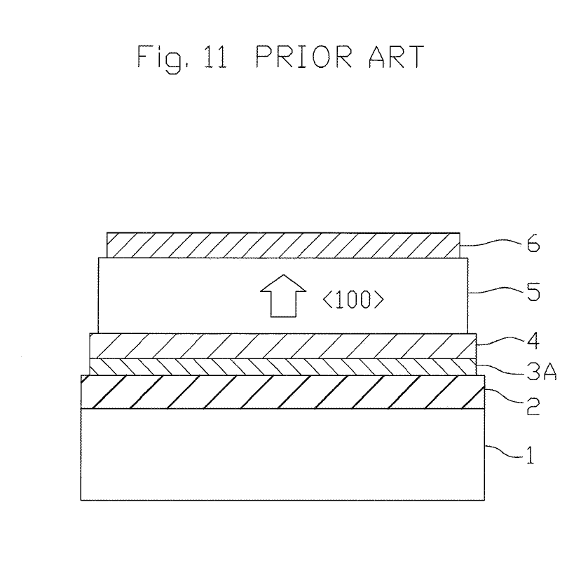

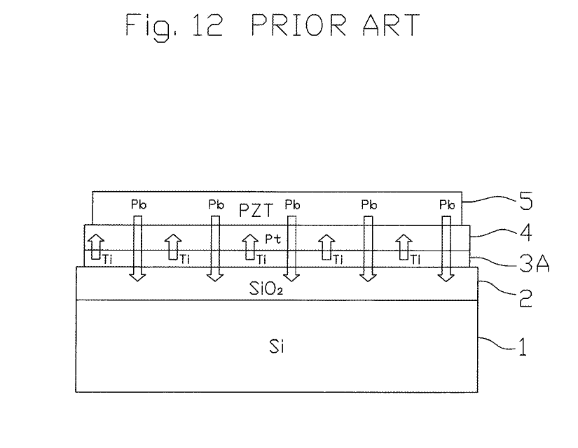

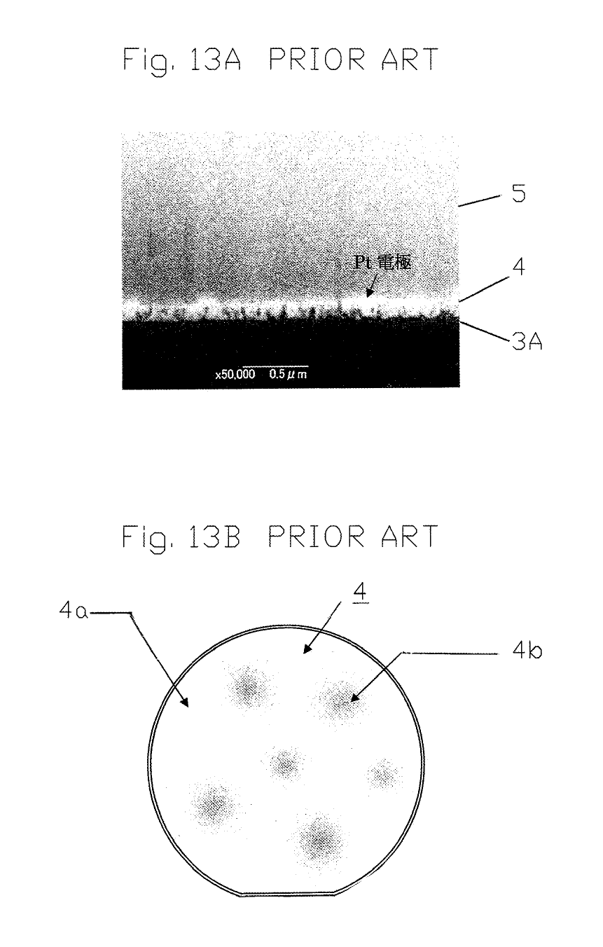

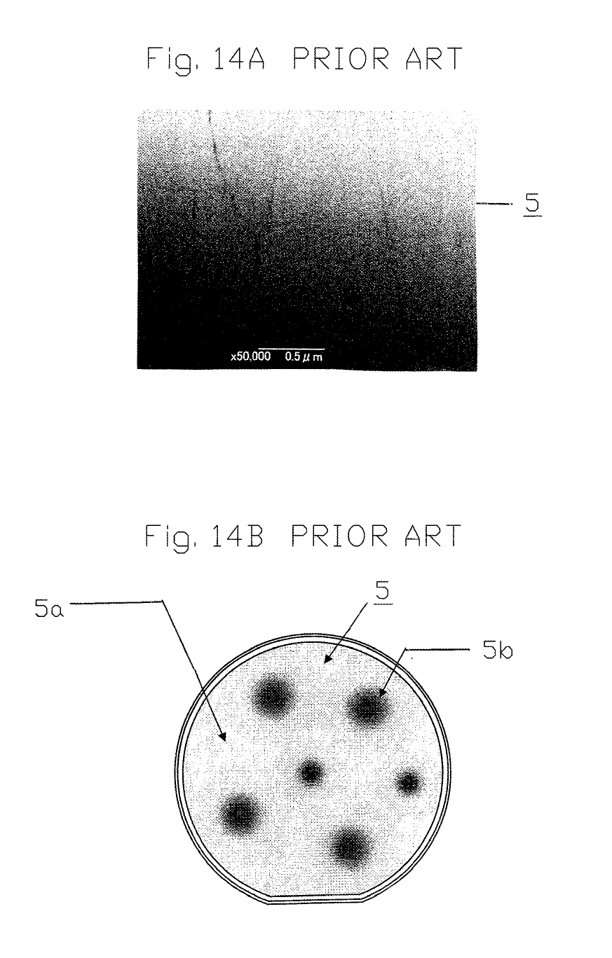

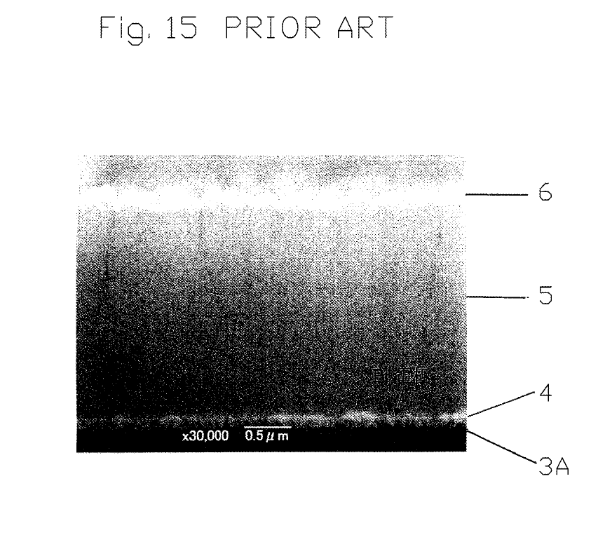

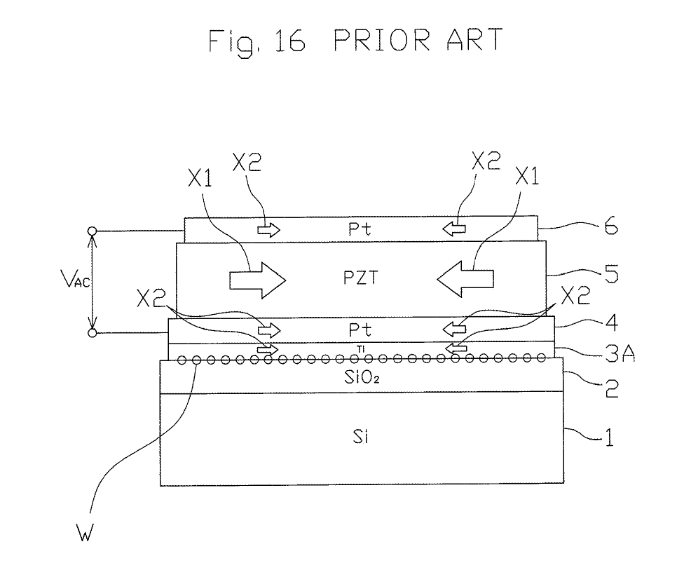

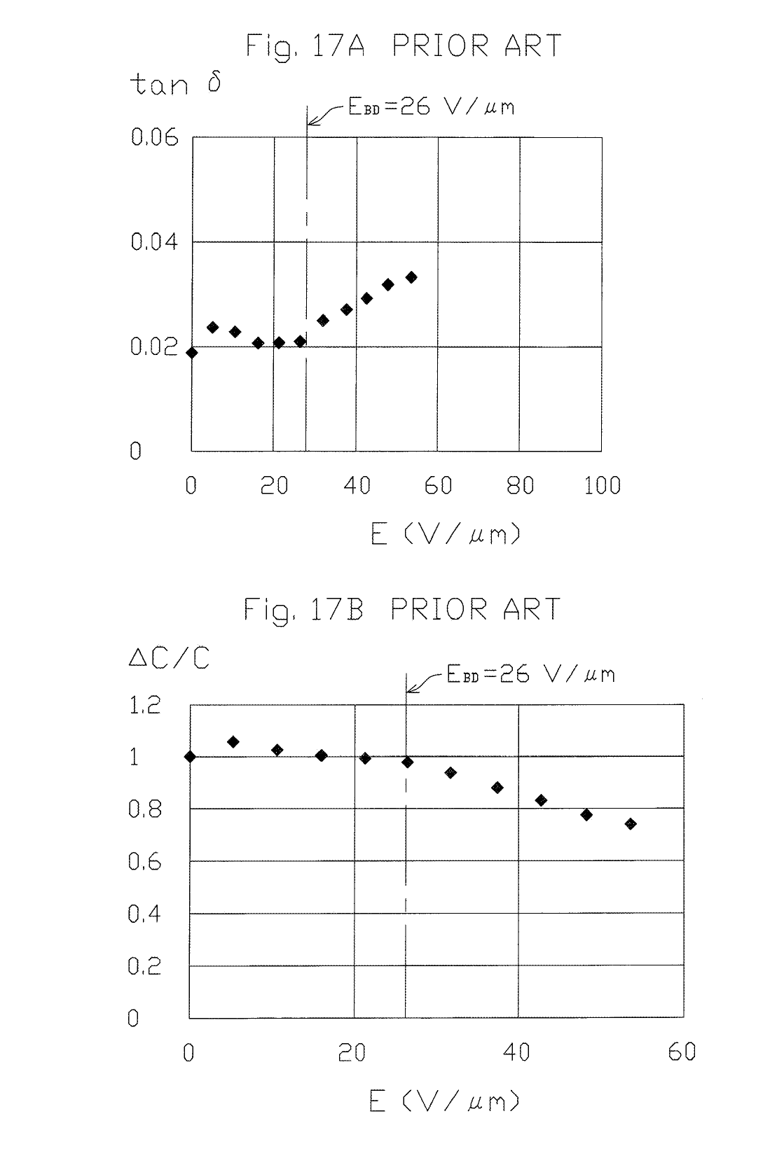

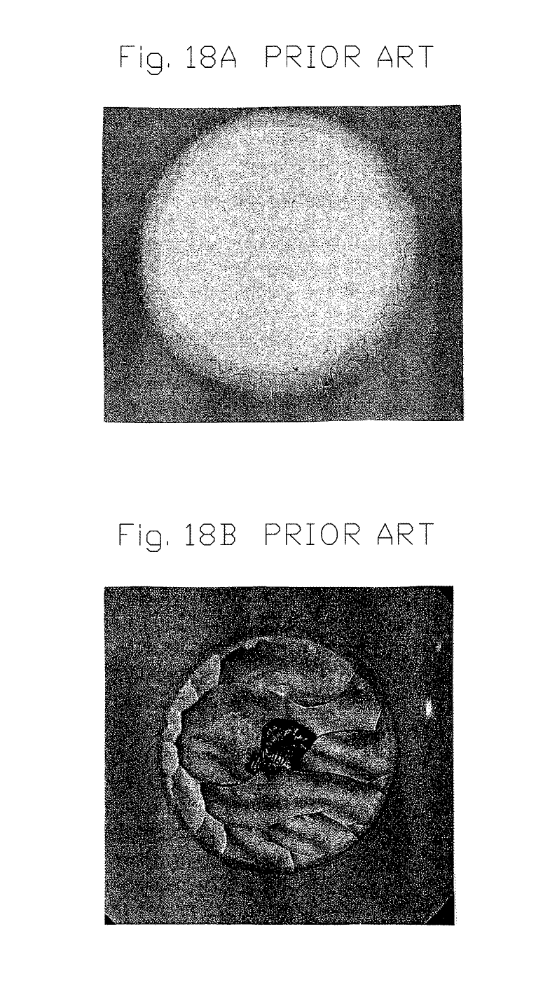

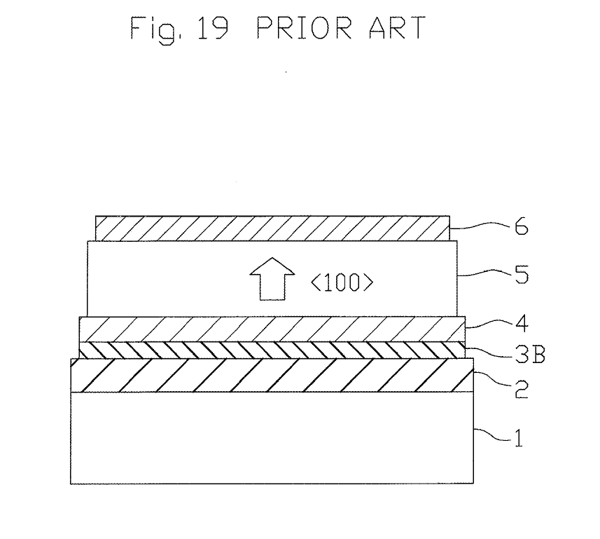

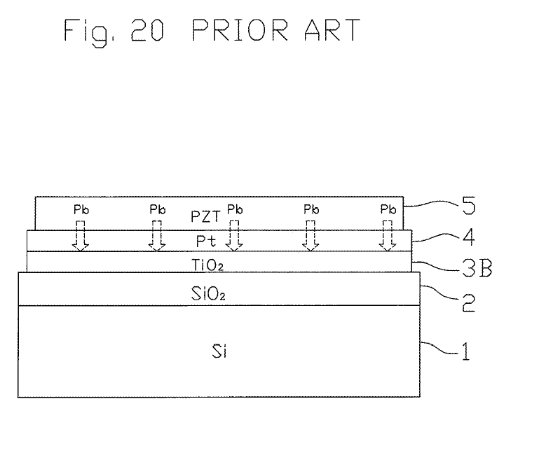

In FIG. 1, which illustrates an embodiment of the piezoelectric actuator according to the presently disclosed subject matter, a Ti/Ti0ₓ adhesive layer 3 consisting of an about 50 nm thick Ti0ₓ (0<x≦2) adhesive layer 31 and an about 10 to 20 nm thick Ti adhesive layer 32 is provided instead of the Ti adhesive layer 3A of FIG. 11 which is about 50 nm thick, so that the amount of Ti is much smaller.

Also, preferably, the composition x of the Ti0ₓ adhesive layer 31 is less than 2, i. e. , 0<x<2, to exclude Ti0₂. That is, the Ti0ₓadhesive layer 31 is obtained by incompletely oxidizing Ti. Therefore, the Ti component of the Ti adhesive layer 32 reacts with Ti0ₓ of the Ti0ₓ adhesive layer 31 and is diffused thereinto. As a result, the Ti0ₓ adhesive layer 31 and the Ti adhesive layer 32 secure a strong adhesion within the Ti/Ti0ₓ adhesive layer 3.

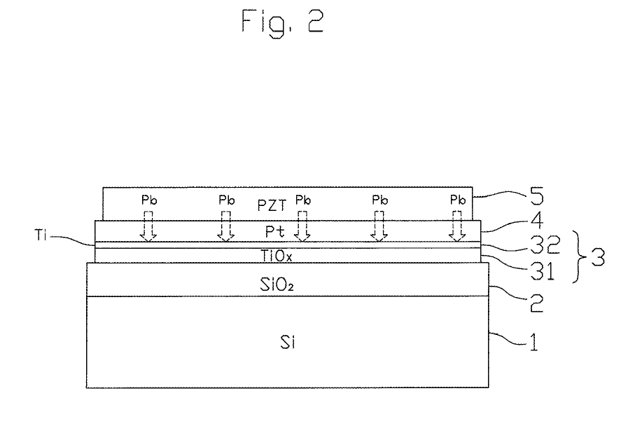

In the piezoelectric actuator of FIG. 1, even when the PZT piezoelectric layer 5 is formed by an arc discharge reactive ion plating (ADRIP) process, a sputtering process or a sol-gel process, so that one wafer including the PZT piezoelectric layer 5 is heated to about 500° C., as illustrated in FIG. 2, since the Ti adhesive layer 32 is very thin, metal Ti is hardly diffused into the Pt lower electrode layer 4. Also, even when the Pb component of the PZT piezoelectric layer 5 reacts with the Pt lower electrode layer 4, the diffusion of the Pb component into the Pt lower electrode layer 4 and the silicon dioxide layer 2 can be prevented by the oxygen component of the Ti0ₓ adhesive layer 31. Further, the oxygen component of the Ti0ₓ adhesive layer 31 prevents the Si component of the silicon dioxide layer 2 from being diffused into the Ti0ₓ adhesive layer 31.

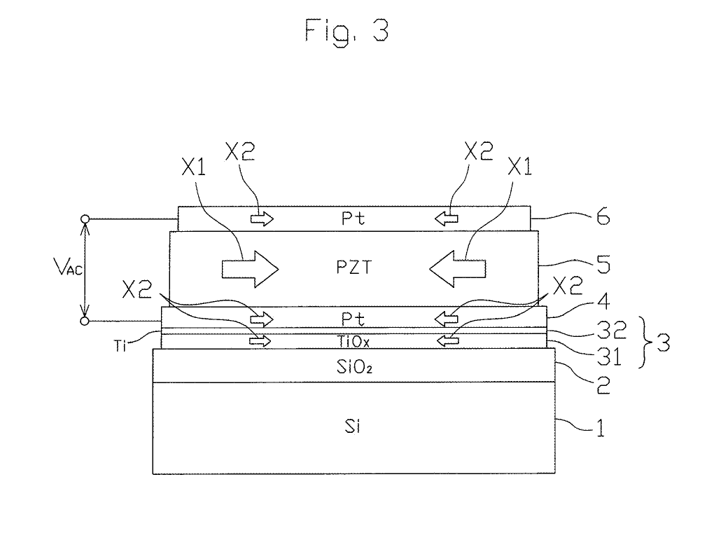

In the piezoelectric actuator of FIG. 1, the adhesion between the Ti0ₓ adhesive layer 31 and the silicon dioxide layer 2 is carried out by an oxide-to-oxide bonding such as covalent bonding or ion bonding, thus securing a strong adhesion. Also, the Ti adhesive layer 32 and the Pt lower electrode layer 4 are carried out by metal-to-metal bonding, thus securing a strong adhesion. Therefore, under a condition where the PZT piezoelectric layer 5 is of a traverse-effect type, when the PZT piezoelectric layer 5 is contracted along the traverse direction as indicated by arrows X1 in FIG. 3, each of the Ti/Ti0ₓ adhesive layer 3, the Pt lower electrode layer 4 and the Pt upper electrode layer 6 would also be contracted by the contraction of the PZT piezoelectric layer 5, as indicated by arrows X2 in FIG. 3. Even in this case, the strong bonding interface between the Ti/Ti0ₓ adhesive layer 3 and the silicon dioxide layer 2 (or the Pt lower electrode layer 4) would not be peeled off by the contraction of the PZT piezoelectric layer 5.

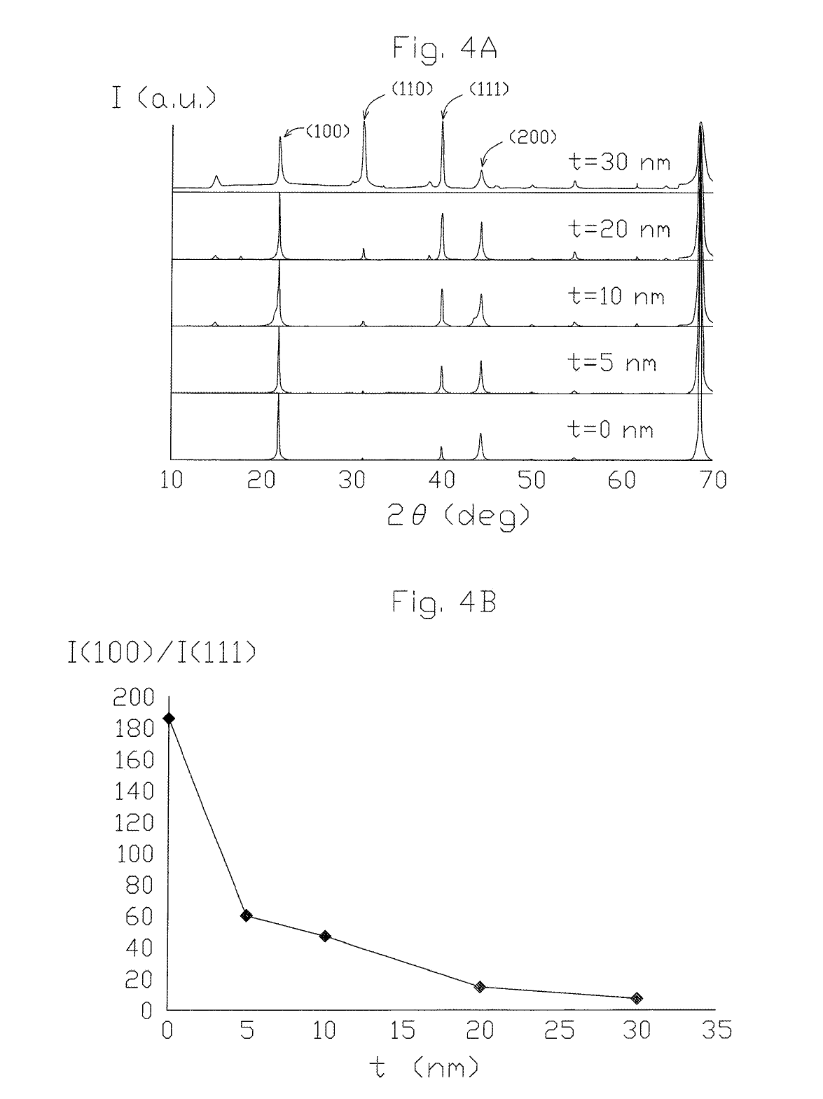

FIG. 4A is a graph illustrating an X-ray analysis pattern of the PZT piezoelectric layer 5 of FIG. 1 representing the crystallizability (piezoelectric characteristics), and FIG. 4B is a graph illustrating orientation characteristics I(100)/I(111) of the PZT piezoelectric layer 5 of FIG. 1.

As illustrated in FIGS. 4A and 4B, when the thickness t of the Ti adhesive layer 32 is within 10 to 20 nm, the piezoelectric characteristics and the orientation characteristics can be secured. That is, since diffusion of Ti of the Ti adhesive layer 32 into the Pt lower electrode layer 4 is suppressed, the deterioration of crystallizability of the Pt lower electrode layer 4 is suppressed.

On the other hand, when the thickness t of the Ti adhesive layer 32 is not larger than 5 nm, adhesion between the Ti adhesive layer 32 and the Pt lower electrode layer 4 would not secure a strong adhesion, so that the piezoelectric characteristics and orientation characteristics of the PZT piezoelectric layer 5 both would deteriorate. Also, when the thickness t of the Ti adhesive layer 32 is not smaller than 30 nm, the amount of Ti diffused from the Ti adhesive layer 32 into the Pt lower electrode layer 4 would increased, so that the piezoelectric characteristics and orientation characteristics of the PZT piezoelectric layer 5 would both deteriorate.

In FIG. 4B, note that I(100)/I(111) between 20 to 40 means a plurality of priority orientations, i.e., the priority orientation (100) and the priority orientation (111) are both controlled simultaneously, thus realizing excellent piezoelectric characteristics (see: JP2003-81694A).

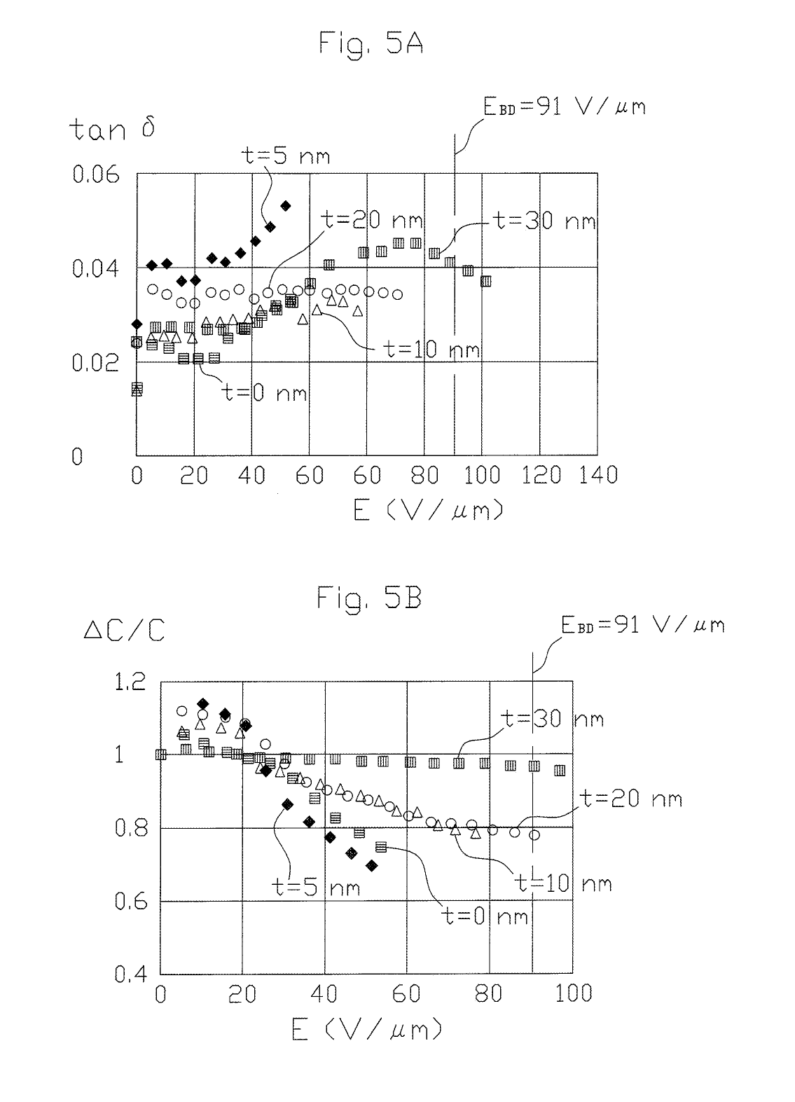

FIGS. 5A and 5B are graphs showing the dielectric loss coefficient tan δ and the capacitance deviation ΔC/C corresponding to the piezoelectric constant (−d₃₁) in response to an electric field E caused by applying an AC voltage V_{AC} between the Pt lower electrode layer 4 and the Pt upper electrode layer 6 of FIG. 1. As illustrated in FIGS. 5A and 5B, when the electric field E of the applied AC voltage V_{AC} is not larger than 91 V/μm (E≦91V/μm), the dielectric loss coefficient tan δ and the capacitance deviation ΔC/C are both unchanged, while the electric field E becomes larger than 26 V/μm (E>26V/μm), both of the dielectric loss coefficient tan δ and the capacitance deviation ΔC/C start to change. In this case, the peripheral surface of the piezoelectric actuator of FIG. 1, i. e. , the peripheral surface of the Pt upper electrode layer 6 starts to be cracked. Further, when the electric field E of the applied AC voltage V_{AC} isincreased, the Pt upper electrode layer 6 associated with the PZT piezoelectric layer 5, the Pt lower electrode layer 4 and the Ti/Ti0ₓ adhesive layer 3 is entirely peeled off, thus inviting electrostatic destruction.

In the piezoelectric actuator of FIG. 1, an electric field E_{BD} corresponding to a breakdown voltage of the applied AC voltage V_{AC} is defined by 91 V/μm, i.e., E_{BD}=91 V/μm.

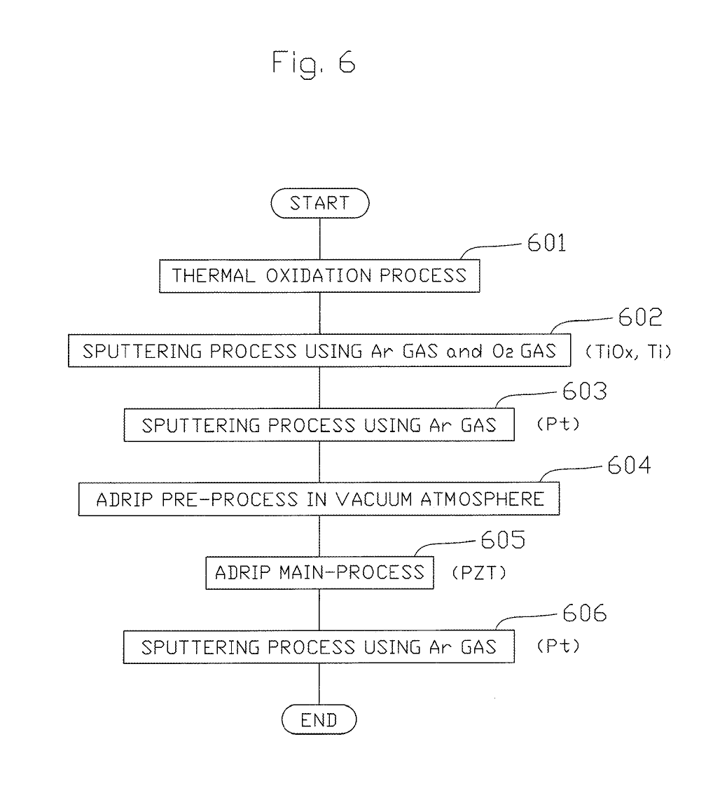

A method for manufacturing the piezoelectric actuator of FIG. 1 is explained next with reference to FIG. 6.

First, referring to step 601, a monocrystalline silicon substrate 1 is thermally oxidized to grow a silicon dioxide (Si0₂) layer 2 thereon. In this case, note that a chemical vapor deposition (CVD) process can be used instead of the thermal oxidization process.

Next, referring to step 602, a Ti0ₓ adhesive layer 31 and a Ti adhesive layer 32 are formed by a sputtering process using Ar gas and 0₂ gas on the silicon oxide layer 2. That is, one wafer is introduced into a sputtering apparatus supplied with Ar gas and 0₂ gas using a Ti target to form an about 50 nm thick Ti0ₓ adhesive layer 31 (0<x≦2). In this case, Ti is preferably incompletely oxidized for Ti0ₓ which has a sheet resistance of about 2×10²Ω/□, i.e., Ti0ₓ is not Ti0₂, but incomplete oxide (0<x<2). Even in this case, however, note that adhesion between the Ti0ₓ adhesive layer 31 and the dioxide layer 2 is carried out by oxide-to-oxide bonding such as covalent bonding or ion bonding, thus securing a strong adhesion. Then, the introduction of 0₂ gas is stopped, and the sputtering apparatus is supplied with only Ar gas to form an about 10 to 20 nm thick the Ti adhesive layer 32.

Next, referring to step 603, a Pt lower electrode layer 4 is formed by a sputtering process using Ar gas on the Ti adhesive layer 32. In this case, adhesion between the Ti adhesive layer 32 and the Pt lower electrode layer 4 is carried out by metal-to-metal bonding, thus securing a strong adhesion.

Next, referring to step 604, before an arc discharge reactive ion plating (ADRIP) main-process at step 605 for forming a PZT piezoelectric layer 5, an ADRIP pre-process is carried out in an ADRIP apparatus in a vacuum atmosphere to heat the monocrystalline silicon substrate 1, the silicon dioxide layer 2, the Ti/Ti0ₓ adhesive layer 3 and the Pt lower electrode layer 4 to about 500° C. This ADRIP pre-process is carried out by an ADRIP apparatus which will be described later.

Next, referring to step 605, the ADRIP main-process is carried out in the same ADRIP apparatus subsequent to the ADRIP pre-process at step 604 to forma PZT piezoelectric layer 5. This ADRIP main-process is carried out by the above-ADRIP apparatus.

Finally, referring to step 606, a Pt upper electrode layer 6 is formed by a sputtering process using Ar gas on the PZT piezoelectric layer 5.

The ADRIP main-process at step 605 has an advantage in that the deposition speed of PZT is higher than the sputtering process. Also, the ADRIP main-process has an advantage in that the substrate temperature is lower, the manufacturing cost is lower, and it is more eco-efficient and more efficient in utilization of materials over the metal organic chemical vapor deposition (MOCVD) process using poisonous organic metal gas.

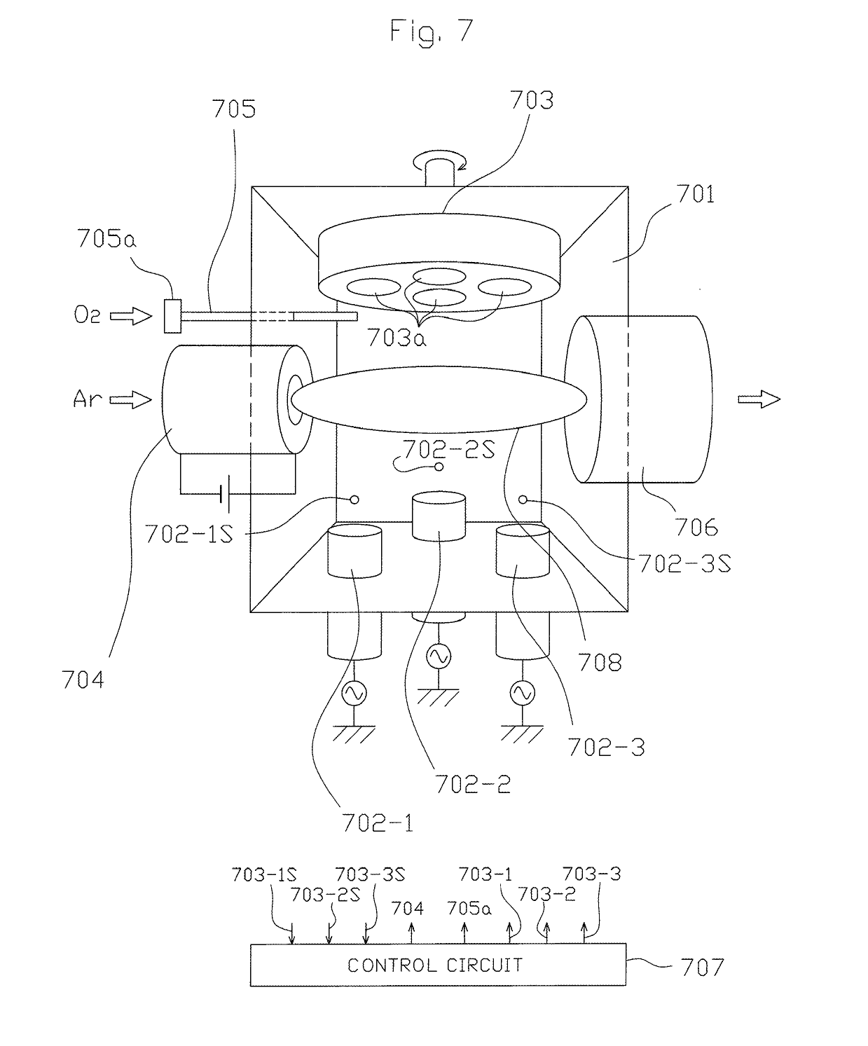

The ADRIP apparatus used for carrying out the ADRIP pre-process at step 604 and the APRIP main-process at step 605 is explained next with reference to FIG. 7 (see: FIG. 1 of JP2001-234331A).

In FIG. 7, provided at a bottom portion of a vacuum chamber 701 is a Pb evaporation source 702-1, a Zr evaporation source 702-2 and a Ti evaporation source 702-3 for independently evaporating Pb, Zr and Ti, respectively.

The Pb evaporation source 702-1, the Zr evaporation source 702-2 and the Ti evaporation source 702-3 are associated with a Pb evaporation amount sensor 702-1S, a Zr evaporation amount sensor 702-2S and a Ti evaporation amount sensor 702-3S, respectively, for detecting Pb, Zr and Ti evaporation amounts within the vacuum chamber 701.

Also, provided at an upper portion of the vacuum chamber 701 is a heater incorporating wafer rotating holder 703 for mounting a wafer 703a.

Further, provided at an upstream side of the vacuum chamber 701 are a pressure gradient type arc discharge plasma gun 704 for introducing insert gas such as Ar gas and He gas thereinto and an 0₂ gas inlet pipe 705 for introducing 0₂ gas thereinto as material for the PZT piezoelectric layer 5. The amount of 0₂ gas introduced into the vacuum chamber 701 is adjusted by an adjusting valve 705a. On the other hand, provided at a downstream side of the vacuum chamber 701 is an exhaust pipe 706 coupled to a vacuum pump (not shown).

A control unit 707 such as a microcomputer is provided to control the entire ADRIP apparatus of FIG. 7. Particularly, the control unit 707 receives signals from the evaporation amount sensors 702-1S, 702-2S and 702-3S to control the evaporation sources 702-1, 702-2 and 702-3 as well as the pressure gradient type arc discharge plasma gun 704 and the adjusting valve 705a.

When the ADRIP apparatus of FIG. 7 carries out the ADRIP main-process at step 1105 of FIG. 11, the control unit 707 operates the pressure gradient type arc plasma gun 704 to receive Ar gas and He gas and generate arc discharge plasma 708 at a high electron density and at a low electron temperature. Also, the control unit 707 operates the adjusting valve 705a to introduce 0₂ gas into the vacuum chamber 701. As a result, a large amount of active atoms and active molecules such as oxygen radicals are generated. On the other hand, Pb vapor, Zr vapor and Ti vapor generated from the Pb evaporation source 702-1, the Zr evaporation source 702-2 and the Ti evaporation source 702-3 react with the above-mentioned active atoms and active molecules and are deposited on the wafer 703a heated at about 500° C. As a result, PbZrₓTi₁₋ₓ0₃ with a composition ratio x is formed on the wafer 703a.

In FIG. 6, ADRIP steps at steps 604 and 605 can be replaced by sputtering steps (see: JP2001-223403A), or sol-gel steps (see: JP2000-094681A), or evaporation steps. That is, at the sputtering steps, the wafer temperature is increased to about 600° C. Also, at the sol-gel steps, since it is impossible to form a thick PZT piezoelectric layer 5, a thin PZT piezoelectric precursor is formed and calcined at a high temperature, thus repeating the formation and calcination of precursors to obtain the thick PZT piezoelectric layer 5.

As explained hereinbefore, the adhesion between the dioxide layer 2 and the Ti0ₓ adhesive layer 31 is carried out by oxide-to-oxide bonding such as covalent bonding or ion bonding, thus securing a strong adhesion, and also, the adhesion between the Ti adhesive layer 32 and the Pt lower electrode layer 4 is carried out by metal-to-metal bonding, thus securing a strong adhesion. Further, if Ti0ₓ of the Ti0ₓ adhesive layer 31 is incomplete oxide (0<x<2), Ti is diffused from the Ti adhesive layer 32 via the Ti/Ti0ₓ interface between the Ti0ₓ adhesive layer 31 and the Ti adhesive layer 32 into the Ti0ₓ adhesive layer 31, thus securing a strong adhesion between the Ti0ₓ adhesive layer 31 and the Ti adhesive layer 32.

Additionally, the Ti component of the Ti adhesive layer 32 into the Pt lower electrode layer 4 is suppressed due to the fact that the Ti adhesive layer 32 is very thin, i.e., the amount of Ti is much smaller. Also, the diffusion of Pb component of the PZT piezoelectric layer 5 into the Pt lower electrode layer 4, the Ti/Ti0ₓ adhesive layer 3 and the dioxide layer 2 is suppressed by the oxygen component of the Ti0ₓ adhesive layer 31. As a result, the deviation of crystallizability of the Pt lower electrode layer 4 is suppressed to suppress the deviation of its surface roughness. Also, the deviation of columnar crystallizability of the PZT piezoelectric layer 5 is suppressed to suppress the deviation of the piezoelectric constant (−d₃₁). Further, the surface roughness of the Pt upper electrode layer 6 is reduced, so that even when a voltage is applied between the Pt lower electrode layer 4 and the Pt upper electrode layer 6, the local focusing of an electric field is relaxed to improve the breakdown voltage characteristics. Thus, the manufacturing yield can be improved.

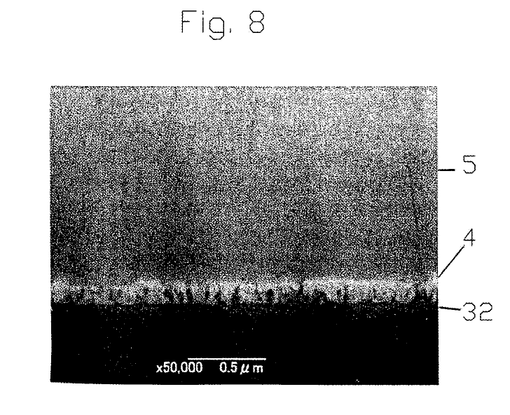

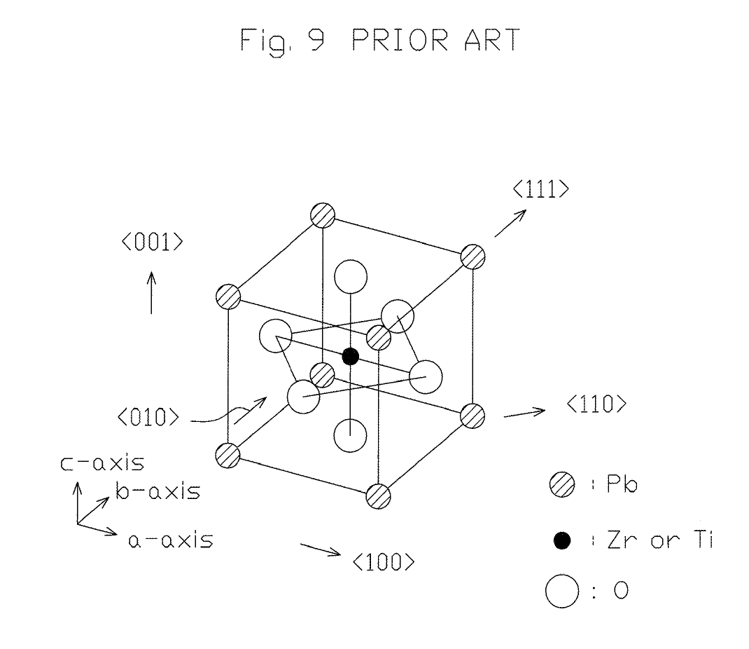

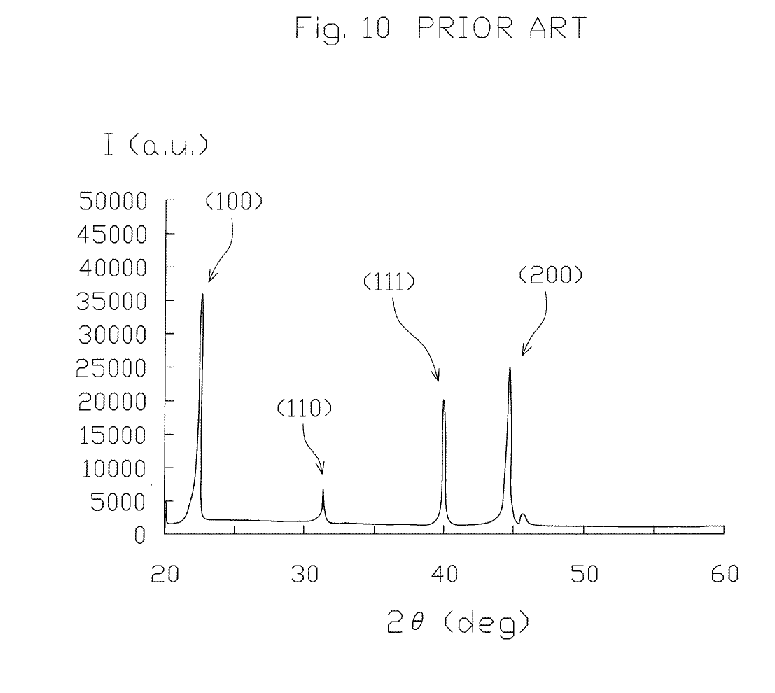

At step 602 of FIG. 6, note that, if the Ti adhesive layer 32 is too thick, the Ti component of the Ti adhesive layer 32 reacts with the Pt lower electrode layer 4 and is diffused thereinto, so that the crystallizability of the Pt lower electrode layer 4 would fluctuate, thus increasing the surface roughness as illustrated in FIG. 8.

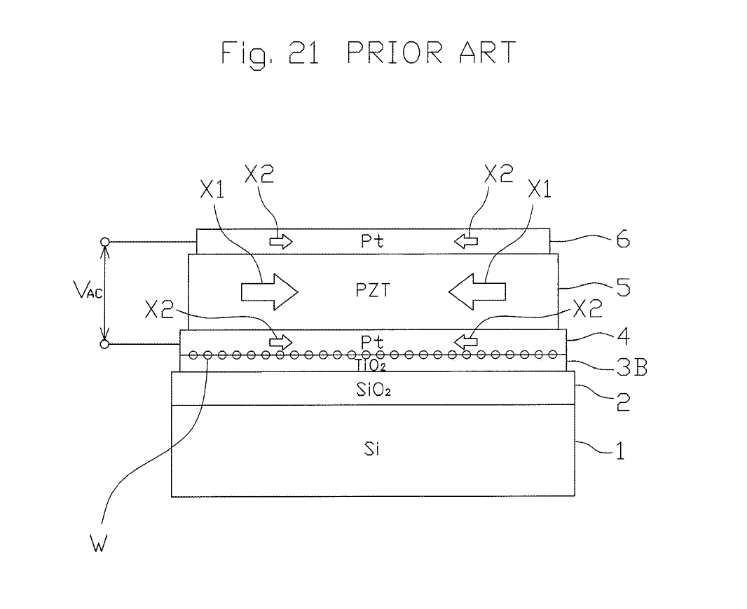

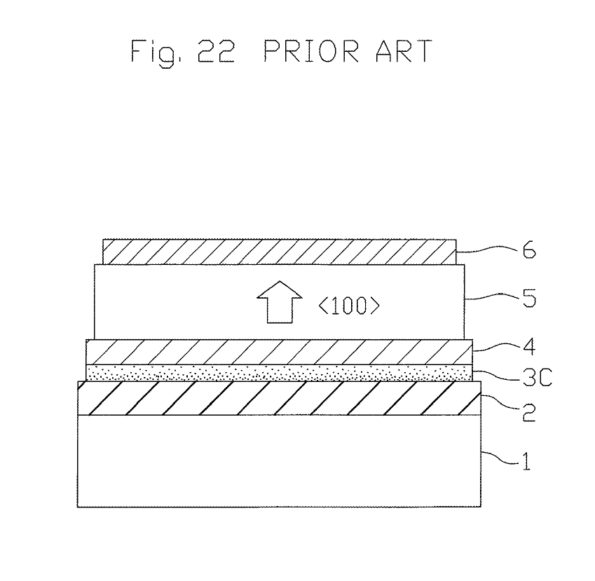

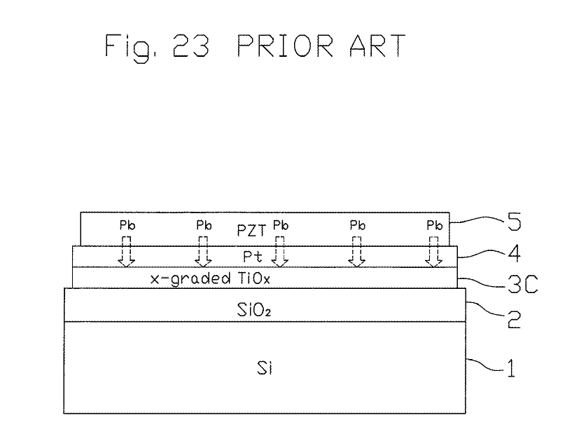

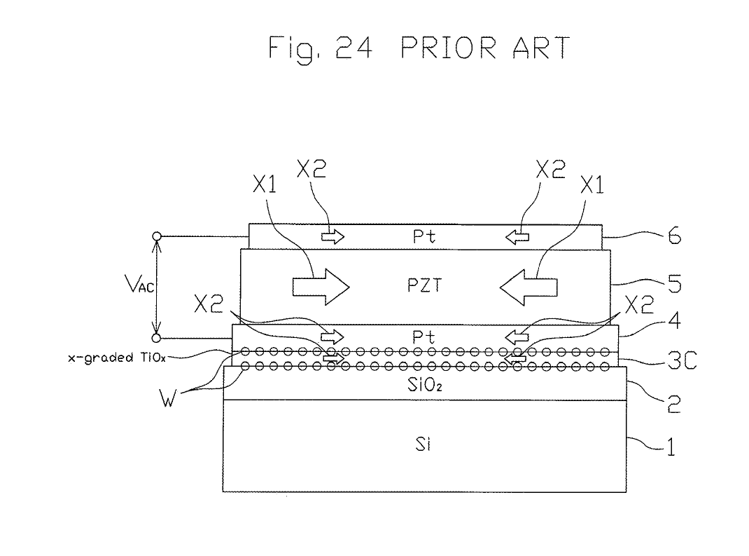

Further, while the breakdown voltage corresponding to electric field E_{BD} in the first and second prior art piezoelectric actuators of FIGS. 11 and 21 is 26 V/μm and 53 V/μm, respectively, the breakdown voltage corresponding to electric field E_{BD} in the piezoelectric actuators of FIG. 1 is 91 V/μm, which means that the breakdown voltage characteristics according the presently disclosed subject matter can remarkably be improved.

It will be apparent to those skilled in the art that various modifications and variations can be made in the presently disclosed subject matter without departing from the spirit or scope of the presently disclosed subject matter. Thus, it is intended that the presently disclosed subject matter covers the modifications and variations of the presently disclosed subject matter provided they come within the scope of the appended claims and their equivalents. All related or prior art references described above and in the Background section of the present specification are hereby incorporated in their entirety by reference.

1. A piezoelectric actuator comprising:
a substrate;
an oxide layer formed on said substrate;
a Ti0ₓ (0<x≦2) adhesive layer formed on said oxide layer;
a Ti adhesive layer formed on said Ti0ₓ adhesive layer;
a Pt lower electrode layer formed on said Ti adhesive layer; and
a PZT piezoelectric layer formed on said Pt lower electrode layer.

2. The piezoelectric actuator as set forth in claim 1, wherein the composition x of said Ti0ₓ adhesivelayer is 0<x<2.

3. The piezoelectric actuator as set forth in claim 1, wherein said Ti adhesive layer is about 10 to 20 nm thick.

4. The piezoelectric actuator as set forth in claim 1, wherein said oxide layer comprises silicon dioxide.

5. A method for manufacturing a piezoelectric actuator comprising:
forming an oxide layer on a substrate;
forming a Ti0ₓ (0<x≦2) adhesive on said oxide layer by a sputtering process using a constant flow rate of inert gas and a flow rate of oxygen gas;
forming a Ti adhesive layer on said Ti0ₓ adhesive layer by a sputtering process using a constant flow rate of inert gas;
forming a Pt lower electrode layer on said Ti adhesive layer; and
forming a PZT piezoelectric layer on said Pt lower electrode layer.

6. The method as set forth in claim 4, further comprising:
heating said substrate, said oxide layer, said Ti0ₓ adhesive layer, said Ti adhesive layer and said Pt lower electrode layer in a vacuum atmosphere before forming said PZT piezoelectric layer.

7. The method as set forth in claim 5, wherein the composition x of said Ti0ₓ adhesive layer is 0<x<2.

8. The method as set forth in claim 5, wherein said Ti adhesive layer is about 10 to 20 nm thick.

9. The method as set forth in claim 5, wherein said oxide layer comprises silicon dioxide.
